(19) United States
(12) Patent Application Publication
(10) Pub. No.: US 2024/0215199 A1
(43) Pub. Date: Jun. 27, 2024

(54) LIQUID-COOLED CABINET AND DATA CENTER COMPUTER ROOM

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN); Jinquan AN, Zhangjiakou City (CN)

(21) Appl. No.: 18/538,781

(22) Filed: Dec. 13, 2023

(30) Foreign Application Priority Data
Dec. 22, 2022 (CN) 202211657804.X

(51) Int. Cl. H05K 7/20; H05K 7/14

(52) U.S. Cl. CPC H05K 7/20272; H05K 7/1497; H05K 7/20236

(57) ABSTRACT

A liquid-cooled cabinet and a data center computer room are disclosed. The liquid-cooled cabinet includes an inner liner having an open accommodation chamber internally provided with a flow equalizing plate, a coolant cavity is formed between the flow equalizing plate and a bottom surface of the accommodation chamber, and the flow equalizing plate is provided with multiple rows of first through-holes. A drainage portion is arranged on a bottom of the first sidewall and a bottom of the second sidewall, and a splitter cavity is arranged below the drainage portion, where a top surface of the splitter cavity is flush with the flow equalizing plate, and the liquid inlet leads to the drainage portion. A liquid outlet is also arranged on the first sidewall and the second sidewall. The liquid-cooled cabinet also includes a top cap that fits in size to an opening of the accommodation chamber.

### CROSS REFERENCE TO RELATED APPLICATION

This application claims priority to Chinese Patent Application No. 202211657804.X, titled “LIQUID-COOLED CABINET AND DATA CENTER COMPUTER ROOM” and filed to the China National Intellectual Property Administration on Dec. 22, 2022, the entire contents of which are incorporated herein by reference.

### TECHNICAL FIELD

The present disclosure relates to the field of refrigeration technology, and more particularly, to a liquid-cooled cabinet and a data center computer room.

### BACKGROUND

With the rapid development of the computer communication industry and electronic technologies, integration density and processing capacity of electronic devices in data center computer rooms are gradually increasing. Accordingly, power consumption of data centers is rapidly increasing, and thus the problem of heat dissipation has become a technical problem to be solved urgently.

Currently, in many data center computer rooms, the electronic devices inside the computer rooms are cooled down by means of air-cooled air conditioners. During heat exchange, air in the computer rooms is cooled down by means of refrigerants, and then heat of the refrigerants is discharged directly. The cooled refrigerants may be used again to cool down the air in the computer rooms, thus achieving effects of cycle refrigeration.

However, air conditioning refrigeration leads to high energy consumption of the data center computer rooms, which seriously wastes resources and causes power usage efficiency (PUE) of the data centers unable to meet requirements.

### SUMMARY

The present disclosure provides a liquid-cooled cabinet and a data center computer room. The data center computer room is cooled down by means of liquid cooling, thereby achieving an objective of reducing energy consumption and improving power usage effectiveness (PUE) for the data center computer room.

In a first aspect, embodiments of the present disclosure provide a liquid-cooled cabinet, which includes:
an inner liner having an open accommodation chamber internally provided with a flow equalizing plate, where a coolant cavity for coolant injection is formed between the flow equalizing plate and a bottom surface of the accommodation chamber, the flow equalizing plate is provided with multiple rows of first through-holes for a coolant to pass through, space above each row of the first through-holes is configured for deploying an electronic device, and a main body of the electronic device is provided with a second through-hole, such that the coolant enters the main body of the electronic device through the second through-hole;
at least one liquid inlet arranged on a first sidewall and a second sidewall of the inner liner, where a drainage portion is arranged on a bottom of the first sidewall and a bottom of the second sidewall, a splitter cavity is arranged below the drainage portion, a top surface of the splitter cavity is flush with the flow equalizing plate, the liquid inlet leads to the drainage portion, and the first sidewall and the second sidewall are two opposite sidewalls of the accommodation chamber;
at least one liquid outlet arranged on the first sidewall and the second sidewall, where a position of the liquid outlet is higher than a position of the liquid inlet;
a backwater cavity arranged on the first sidewall and the second sidewall and keeping away from the drainage portion, wherein an inlet of the backwater cavity is positioned in upper space of the accommodation chamber, an outlet of the backwater cavity is connected to the liquid outlet, and the upper space is space above the electronic device; and
a top cap covering an opening of the accommodation chamber.

In a second aspect, the embodiments of the present disclosure provide a data center computer room, which includes a computer room and the method as described in the first aspect or various implementations in the first aspect.

According to the liquid-cooled cabinet and the data center computer room provided in the embodiments of the present disclosure, the liquid-cooled cabinet includes an inner liner having an open accommodation chamber internally provided with a flow equalizing plate, a coolant cavity is formed between the flow equalizing plate and a bottom surface of the accommodation chamber, and the flow equalizing plate is provided with multiple rows of first through-holes. A drainage portion is arranged on a bottom of the first sidewall and a bottom of the second sidewall of the inner liner, and a splitter cavity is arranged below the drainage portion, where a top surface of the splitter cavity is flush with the flow equalizing plate, and the liquid inlet leads to the drainage portion. The first sidewall and the second sidewall are two opposite sidewalls of the accommodation chamber. A liquid outlet is also arranged on the first sidewall and the second sidewall. The liquid-cooled cabinet also includes a top cap that fits in size to an opening of the accommodation chamber. After entering from the liquid inlet, the coolant enters the drainage portion, and then enters the coolant cavity below the flow equalizing plate through the drainage portion. Next, the coolant enters the space above the flow equalizing plate through the first through-hole on the flow equalizing plate. The main body of the electronic device is provided with a second through-hole, such that the coolant enters the main body of the electronic device through the second through-hole and takes away heat generated by the electronic device. By adopting this solution, the data center computer room is cooled down by means of liquid cooling, thereby achieving an objective of reducing energy consumption and improving power usage effectiveness (PUE) for the data center computer room. Moreover, the liquid-cooled cabinet can ensure an operating temperature of an electronic device, achieve precise control of the operating temperature, and minimize environmental impacts. Compared to air cooling, this solution greatly reduces power consumption and floor area, reduces noise pollution, saves energy, and reduces water consumption.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is an overall schematic diagram of a liquid-cooled cabinet according to an embodiment of the present disclosure;

FIG. 2A is an exploded view of FIG. 1;

FIG. 2B is another exploded view of FIG. 1;

FIG. 2C is a top view of FIG. 1;

FIG. 2D is a front view of FIG. 1;

FIG. 2E is an upward view of FIG. 1;

FIG. 2F is a schematic rear view of FIG. 1;

FIG. 2G is a left view of FIG. 1;

FIG. 2H is a right view of FIG. 1;

FIG. 3 is a schematic structural diagram showing other parts of the liquid-cooled cabinet except for a top cap according to an embodiment of the present disclosure;

FIG. 4A is a front view of FIG. 3;

FIG. 4B is a top view of FIG. 3;

FIG. 4C is a left view of FIG. 3;

FIG. 4D is a sectional view of a first sidewall of FIG. 4B;

FIG. 4E is a right view of FIG. 3;

FIG. 4F is a sectional view of a second sidewall of FIG. 4B;

FIG. 4G is a sectional view of a third sidewall of FIG. 4B;

FIG. 4H is a sectional view of a fourth sidewall of FIG. 4B;

FIG. 5 is a schematic diagram of the top cap of the liquid-cooled cabinet according to an embodiment of the present disclosure;

FIG. 6A is an upward view of FIG. 5;

FIG. 6B is a top view of FIG. 5;

FIG. 6C is a front view of FIG. 5;

FIG. 6D is a split view of FIG. 5;

FIG. 7 is a schematic structural diagram of a first protective element of the liquid-cooled cabinet according to an embodiment of the present disclosure;

FIG. 8A is a schematic diagram showing a left side surface of the first protective element shown in FIG. 7;

FIG. 8B is a schematic diagram showing a front side surface of the first protective element shown in FIG. 7;

FIG. 8C is a schematic diagram showing a bottom surface of the first protective element shown in FIG. 7; and

FIG. 9 is a schematic structural diagram of a second protective element of the liquid-cooled cabinet according to an embodiment of the present disclosure.

### DETAILED DESCRIPTION

Detailed description of implementations of the present disclosure will further be made below with reference to drawings to make the above objectives, technical solutions and advantages of the present disclosure more apparent.

In the description of the present disclosure, it is to be understood that the orientations or positions represented by the terms of “center”, “longitudinal”, “transverse”, “length”, “width”, “thickness”, “up”, “down”, “front”, “back”, “left”, “right”, “vertical”, “horizontal”, “top”, “bottom”, “in”, “out”, “clockwise”, “anticlockwise”, “axial”, “radial”, “circumferential”, and the like are based on the orientations or positions as shown in the accompanying figures, they are merely for ease of a description of the present disclosure and a simplified description instead of being intended to indicate or imply the apparatus or element to have a special orientation or to be configured and operated in a special orientation. Thus, they cannot be understood as limiting of the present disclosure.

In the present disclosure, unless specified or limited otherwise, terms “mounted”, “connected”, “coupled”, “fixed” and so on should be understood in a broad sense, which may be, for example, a fixed connection, a detachable connection or integrated connection, a direct connection or indirect connection by means of an intermediary, an internal communication between two elements or an interaction relationship between two elements. For those of ordinary skill in the art, concrete meanings of the above terms in the present disclosure may be understood based on concrete circumstances.

It should be noted that in the description of the present disclosure, the terms “first” and “second” are used only for purposes of description of different components, and cannot be understood as indicating or implying sequential relationships, relative importance, or implying the number of indicated technical features. Thus, the feature defined with “first” and “second” may explicitly or implicitly include at least one such feature.

The data center is a major consumer of electricity, and electronic devices and refrigeration units that operate continuously throughout the year consume a large amount of electricity. Adopting effective heat dissipation methods to reduce the power consumption of refrigeration units in the data center is conducive to achieving energy conservation throughout the entire data center.

Air cooling technologies are used in most of the existing data center computer rooms to cool down the electronic devices. One data center computer room needs to be provided with many air conditioners. Cold air generated by the air conditioners takes away heat generated inside the electronic devices, to cool down the data center computer rooms.

However, because there is a larger amount of heat generated by the electronic devices in the computer rooms, a large amount of cold air is required to dissipate heat from the electronic devices, which in turn requires the air conditioners to operate continuously to generate the cold air, resulting in huge power consumption and high PUE of the data centers.

On this basis, embodiments of the present application provide a liquid-cooled cabinet and a data center computer room. The data center computer room is cooled down by means of liquid cooling, thereby achieving an objective of reducing energy consumption and improving power usage effectiveness (PUE) for the data center computer room.

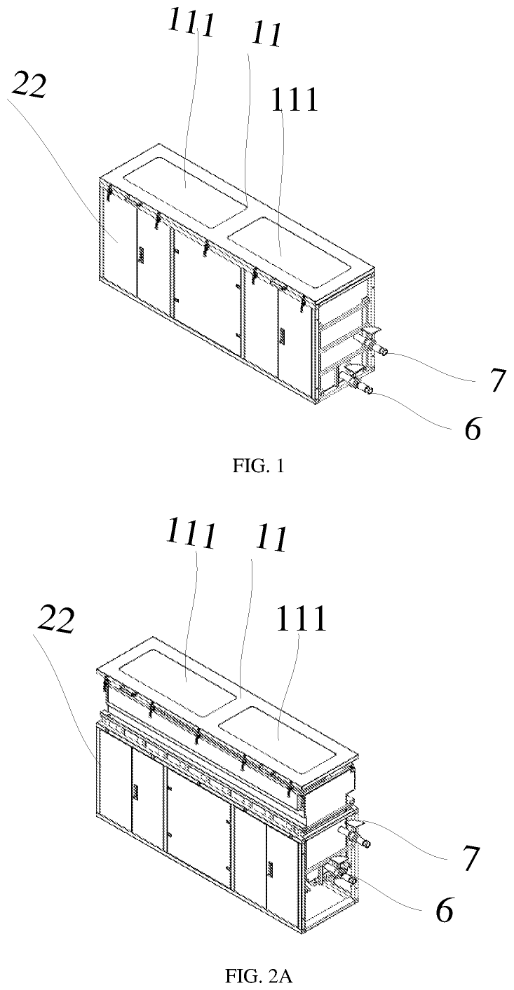

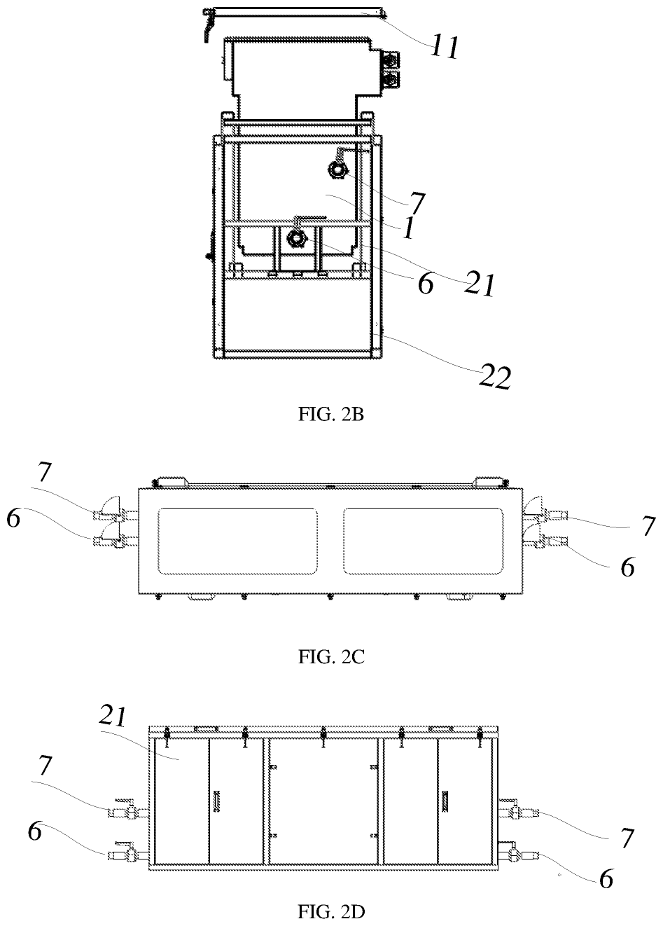

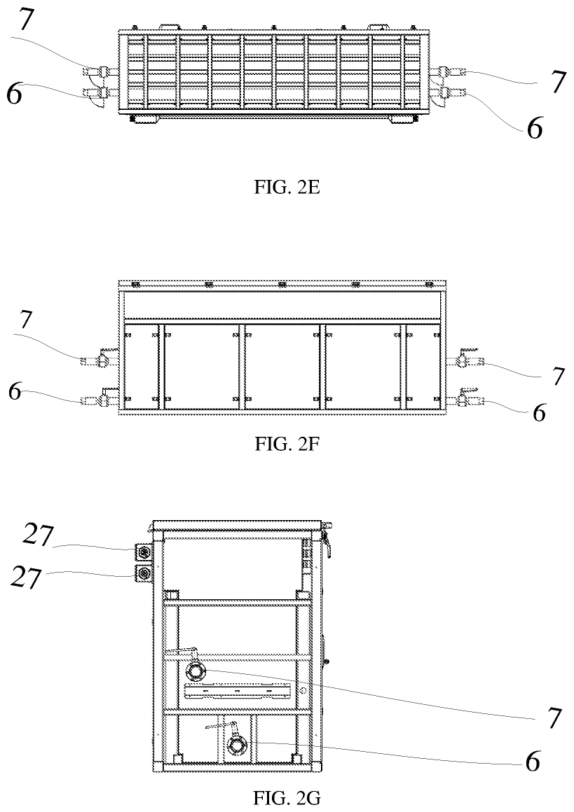

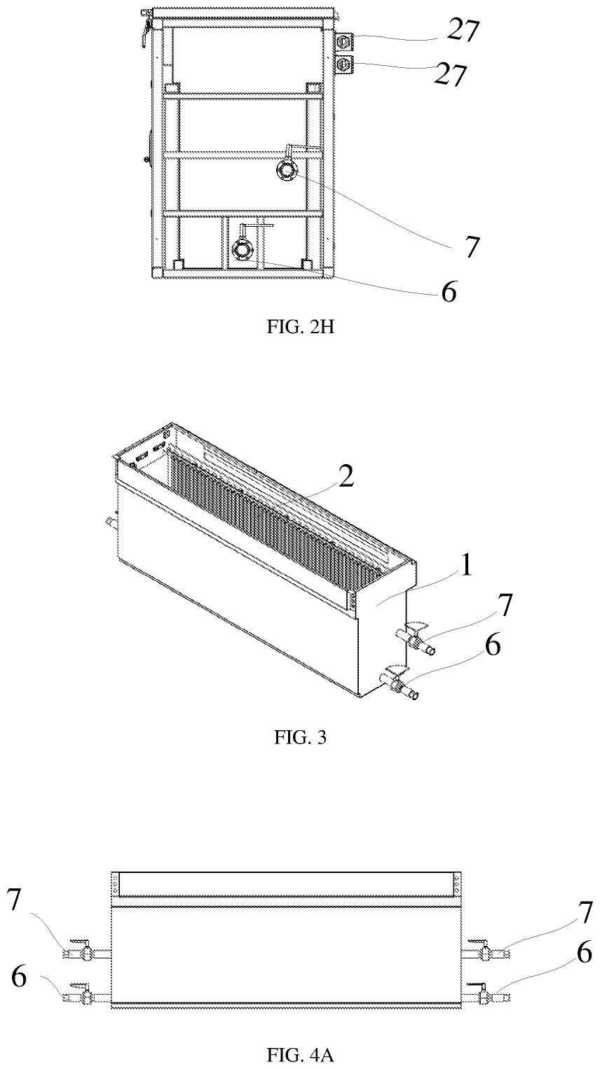

FIG. 1 is an overall schematic diagram of the liquid-cooled cabinet according to an embodiment of the present disclosure. FIG. 2A is an exploded view of FIG. 1, FIG. 2B is a side view of FIG. FIG. 2A, FIG. 2C is a top view of FIG. 1, FIG. 2D is a front view of FIG. 1, FIG. 2E is an upward view of FIG. 1, FIG. 2F is a schematic rear view of FIG. 1, FIG. 2G is a left view of FIG. 1, and FIG. 2H is a right view of FIG. 1.

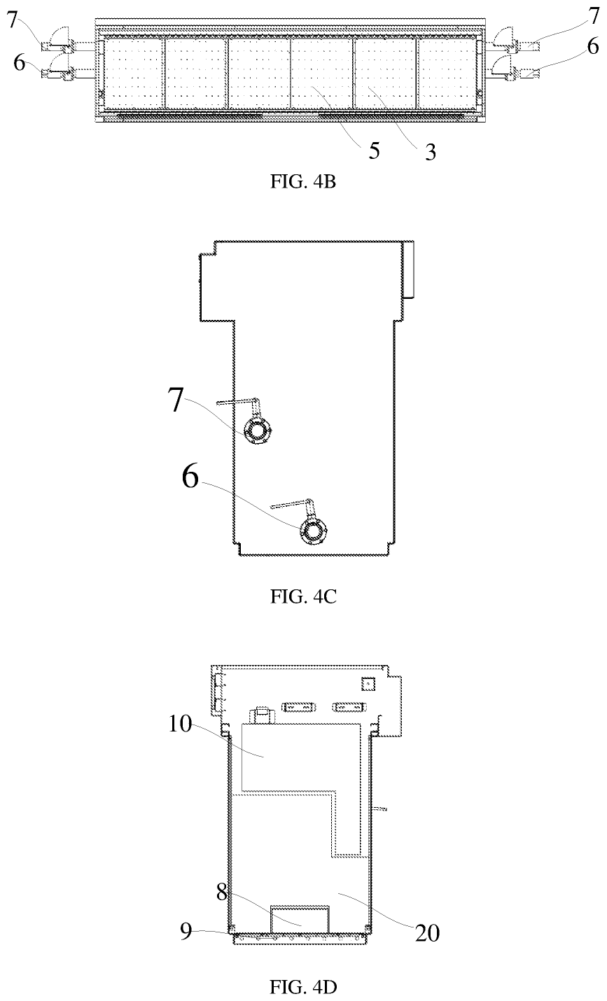

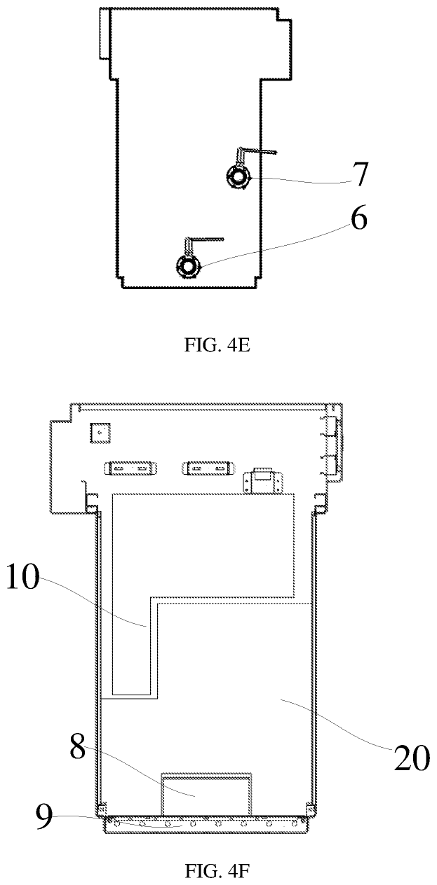

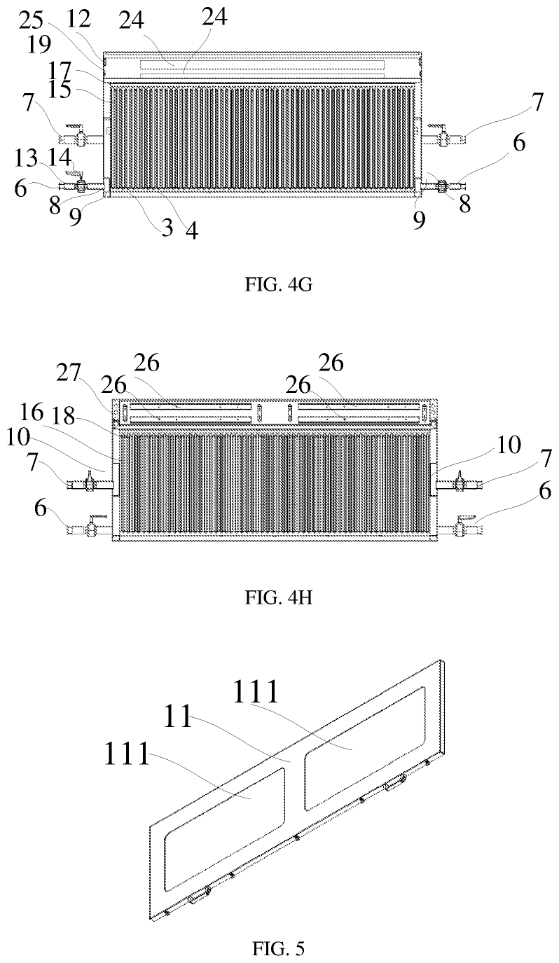

FIG. 3 is a schematic structural diagram showing other parts of the liquid-cooled cabinet except for a top cap according to an embodiment of the present disclosure. FIG. 4A is a front view of FIG. 3, FIG. 4B is a top view of FIG. 3, FIG. 4C is a left view of FIG. 3, FIG. 4D is a sectional view of a first sidewall of FIG. 4B, FIG. 4E is a right view of FIG. 3, FIG. 4F is a sectional view of a second sidewall of FIG. 4B, FIG. 4G is a sectional view of a third sidewall of FIG. 4B, and FIG. 4H is a sectional view of a fourth sidewall of FIG. 4B.

Referring to FIGS. 1 to 4H, the liquid-cooled cabinet includes an inner liner 1 having an open accommodation chamber 2 internally provided with a flow equalizing plate 3, where a certain distance is provided between the flow equalizing plate 3 and the bottom of the accommodation chamber 2, such that a coolant cavity 4 is formed between the flow equalizing plate 3 and a bottom surface of the accommodation chamber 2. The flow equalizing plate 3 is provided with multiple rows of first through-holes 5 for a coolant to pass through, space above each row of the first through-holes 5 is configured for deploying an electronic device, and a main body of the electronic device is provided with a second through-hole, such that the coolant enters the main body of the electronic device through the second through-hole. The main body of the electronic device is not shown in the figures. The electronic device may be a device generating a large amount of heat, such as a server in the data center computer room.

For example, the inner liner 1 is a rectangular cuboid, where front, rear, left and right side surfaces and a bottom surface of the inner liner 1 are, for example, stainless steel plates, which are welded using welding technologies to obtain the inner liner 1, thereby ensuring that the inner liner 1 can store water. The stainless steel plate at least is made of 304 stainless steel, and may also be made of other metals that are not easily deformed.

At least one liquid inlet 6 and at least one liquid outlet 7 are arranged on the first sidewall and the second sidewall of the inner liner 1, where a position of the liquid outlet 7 is higher than that of the liquid inlet 6. The first sidewall is also referred to as a left sidewall, and the second sidewall is also referred to as a right sidewall. Obviously, the first sidewall and the second sidewall are two opposite sidewalls of the accommodation chamber. A drainage portion 8 is arranged on a bottom of the first sidewall and a bottom of the second sidewall, and a splitter cavity 9 is arranged below the drainage portion 8, where a top surface of the splitter cavity 9 is flush with the flow equalizing plate 3. The liquid inlet 6 leads to the drainage portion 8. After entering from the liquid inlet 6, the coolant enters the drainage portion 8, and then enters the coolant chamber 4 below the flow equalizing plate 3 through the drainage portion 8. Next, the coolant enters space above the flow equalizing plate 3 through the first through-hole 5 on the flow equalizing plate 3, i.e. the space above the first through-hole 5. The main body of the electronic device is provided with a second through-hole, such that the coolant enters the main body of the electronic device through the second through-hole and takes away heat generated by the electronic device.

A backwater cavity 10 is arranged on the first sidewall and the second sidewall of the inner liner 1, and the inner liner 1 keeps away from the drainage portion 8, where an inlet of the backwater cavity 10 is positioned in upper space of the accommodation chamber, an outlet of the backwater cavity 10 is connected to the liquid outlet 7, and the upper space is space above the electronic device.

A pipe 13 is arranged between the liquid inlet 6 and the drainage portion 8, and a valve 14 is arranged on the pipe 13. When the valve 14 is opened, the external coolant is injected through the liquid inlet 6. The valve 14 may be a butterfly valve, etc. It is easy to open and close the valve 14, which has a smaller dimension and thus does not occupy much space. When the butterfly valve is damaged, it is only required to replace the butterfly valve, without evacuating the coolant in the accommodation chamber before the replacement, which not only improves efficiency of operation and maintenance, but also reduces risk of leakage of the coolant in the accommodation chamber 2 caused by damage of the valve 14. In addition, a flow rate of the coolant injected into the drainage portion 8 can be controlled by means of the valve 14.

When the coolant needs to be injected, the electronic device is inserted into the accommodation chamber 2, and a liquid injection trolley is connected to the liquid inlet 6. After the liquid inlet 6 is locked with the liquid injection trolley by means of a buckle, the valve 14 is opened, and the coolant enters the pipe 13 through the liquid inlet 6, and enters the drainage portion 8 under the guidance of the pipe 13, and then enters the splitter cavity 9. The drainage portion 8 is used to guide the coolant to enter the bottom of the accommodation chamber 2, and avoid causing impacts to components on the main body of the electronic device due to rapid flow rate of the liquid inlet 6, thereby preventing failure of the electronic device. The splitter cavity 9 is used to transfer the coolant entering the drainage portion 8 into the coolant chamber 4 below the flow equalizing plate 3. After the coolant enters the coolant chamber 4, due to continuous injection of the coolant, the coolant enters the space above the first through-hole 5 through the first through-hole 5 on the flow equalizing plate 3. The electronic device is deployed in the space above the first through-hole 5, a second through-hole is arranged on the main body of the electronic device, and the coolant enters the main body of the electronic device through the second through-hole. The second through-hole may be positioned on the bottom of the electronic device or on each side surface of the electronic device.

After passing through the electronic device, the coolant takes away the heat generated by the electronic device to the upper space. Based on principles of thermal expansion and contraction of liquids, the heat flow may be positioned in the upper space, that is, on the top of the electronic device. As the coolant is continuously injected from the liquid inlet 6, a liquid level of the coolant in the accommodation chamber 2 gradually rises. When a height of the coolant is higher than the first sidewall and the second sidewall of the inner liner 1, i.e. higher than the inlet of the backwater cavity 10 on the left sidewall and the right sidewall, the heat flow enters the backwater cavity 10 and then is transported to outside through the outlet 7. The backwater cavity 10 is used to prevent the coolant from flowing out of the liquid outlet 7 after half of the coolant is injected into the accommodation chamber 2, otherwise effects of thermal cycling cannot be achieved, and complete heat exchange of the electronic device cannot achieved.

Referring to FIGS. 4D and 4F, in the embodiments of the present disclosure, the backwater cavity 10 is approximately in an inverted “L” shape, which increases backwater area to some extent, i.e. increases a volume of the backwater cavity 10. Advantages are as below. After the coolant enters the coolant chamber 4, under a resistance of the flow equalizing plate 3 and the components in the electronic device, flow rates of cold and hot flows are different, the flow rate of the cold flow is lower, while the flow rate of the hot flow is higher. When the backwater area of the backwater cavity 15 is smaller, there may occur a phenomenon that the electronic device is exposed outside the coolant and the liquid level suddenly drops due to slow supplement of the coolant, which is not desirable. In the embodiments of the present disclosure, by increasing the area of the backwater cavity 10, the heat flow entering the backwater cavity 10 is increased, which is more than the heat flow flowing out of the liquid outlet 7. Therefore, most of the heat flow is stored in the accommodation chamber 2, such that there is no liquid level difference.

Referring to FIGS. 3 to 4H, the liquid-cooled cabinet provided in the embodiments of the present disclosure can completely immerse the electronic device such as the server in the coolant, and circulate the coolant in the liquid-cooled cabinet by means of an external heat exchange device to take away excess heat from the electronic device, thereby ensuring that the temperature of each electronic device remains constant for a long time, ensuring normal operation of the electronic device, and reducing maintenance time and labor efficiency. Moreover, immersion environment effectively avoids adverse effects of moisture, dust, and other factors on the electronic device. In addition, there is no need for a fan, thus effectively solving noise and vibration problems.

The liquid-cooled cabinet provided in the embodiments of the present disclosure includes an inner liner having an open accommodation chamber internally provided with a flow equalizing plate, a coolant cavity is formed between the flow equalizing plate and a bottom surface of the accommodation chamber, and the flow equalizing plate is provided with multiple rows of first through-holes. A drainage portion is arranged on a bottom of the first sidewall and a bottom of the second sidewall of the inner liner, and a splitter cavity is arranged below the drainage portion, where a top surface of the splitter cavity is flush with the flow equalizing plate, and the liquid inlet leads to the drainage portion. The first sidewall and the second sidewall are two opposite sidewalls of the accommodation chamber. A liquid outlet is also arranged on the first sidewall and the second sidewall. The liquid-cooled cabinet also includes a top cap that fits in size to an opening of the accommodation chamber. After entering from the liquid inlet, the coolant enters the drainage portion, and then enters the coolant cavity below the flow equalizing plate through the drainage portion. Next, the coolant enters the space above the flow equalizing plate through the first through-hole on the flow equalizing plate. The main body of the electronic device is provided with a second through-hole, such that the coolant enters the main body of the electronic device through the second through-hole and takes away heat generated by the electronic device. By adopting this solution, the data center computer room is cooled down by means of liquid cooling, thereby achieving an objective of reducing energy consumption and improving power usage effectiveness (PUE) for the data center computer room. Moreover, the liquid-cooled cabinet can ensure an operating temperature of an electronic device, achieve precise control of the operating temperature, and minimize environmental impacts. Compared to air cooling, this solution greatly reduces power consumption and floor area, reduces noise pollution, saves energy, and reduces water consumption.

Referring to FIG. 4G and FIG. 4H again, alternatively, a first guide bar 15 is arranged on a third sidewall of the accommodation chamber 2, and a second guide bar 16 is arranged on a fourth sidewall of the accommodation chamber 2. The third sidewall and the fourth sidewall are the two opposite sidewalls of the accommodation chamber. The third sidewall is also referred to as a front sidewall of the accommodation chamber, and the fourth sidewall is also referred to as a rear sidewall of the accommodation chamber. The first guide bar 15 and the second guide bar 16 are configured to guide the electronic device to enter the accommodation chamber 2. The first guide bar 15 and the second guide bar 16 are used to guide the electronic device to enter the accommodation chamber 2, and also can ensure normal insertion and removal of each electronic device.

Alternatively, the inner liner 1 is also provided with a waterproof joint mounting hole 28, which is used for connecting signal wires of the electronic devices or switches to peripheral devices, without occurrence of a phenomenon that the coolant in the accommodation chamber 2 leaks and sublimates to gas.

In the embodiments of the present disclosure, widths of the first guide bar 15 and the second guide bar 16 that guide the same electronic device may be equal or not equal. For example, when the electronic device is a rectangular cuboid, the widths of the first guide bar 15 and the second guide bar 16 are equal. For example, when one of two opposite faces of the electronic device is wider and the other one is narrower, the widths of the first guide bar 15 and the second guide bar 16 are not equal.

In addition, the widths of any two first guide bars 15 among a plurality of first guide bars 15 may be equal or not equal. This is because some electronic devices are narrower, while some other electronic devices are wider. The specific widths of the first guide bar 15 and the second guide bar 16 may be set according to a size of the electronic device.

By adopting this solution, the objective of quickly guiding and mounting the electronic device into the accommodation chamber is achieved.

Alternatively, in the above embodiment, a first mounting plate 17 is arranged on the third sidewall of the accommodation chamber 2, and a second mounting plate 18 is arranged on the fourth sidewall of the accommodation chamber, where the first mounting plate 17 and the second mounting plate 18 are respectively provided with a mounting hole. When the electronic device is inserted in place under the guidance of the first guide bar 15 and the second guide bar 16, a nut on the electronic device is locked with the mounting hole to achieve the objective of fixing the electronic device.

In addition, after the electronic device is installed in place, the first mounting plate 17 and the second mounting plate 18 can also play a certain supporting role, preventing the electronic device from floating due to its weight being less than a buoyancy force generated by the coolant when it is immersed in the coolant.

Alternatively, in the above embodiment, a flow baffle 19 is arranged on the third sidewall of the accommodation chamber 2, the where the flow baffle is arranged behind the first mounting plate 17 to prevent the coolant from entering a power supply unit of the electronic device.

For example, when the electronic device generates too much heat, the coolant is likely to boil, and the boiling coolant may easily flow to a power distribution unit (PDU), which is the power supply unit of the electronic device, mainly including a socket part, thereby damaging the power supply unit or even causing accidents in severe cases. Therefore, by providing the flow baffle 19, the first mounting plate 17 and the flow baffle 19 are arranged in tandem, which can prevent the coolant in the accommodation chamber 2 from entering the power supply unit of the electronic device after the coolant level rises.

Referring to FIGS. 4D and 4F, alternatively, in the above embodiment, the liquid-cooled cabinet also includes a filling block 20, which is arranged between the drainage portion 8 and the backwater cavity 10. By providing the filling block 20, amount of the coolant injected into the accommodation chamber 2 can be reduced.

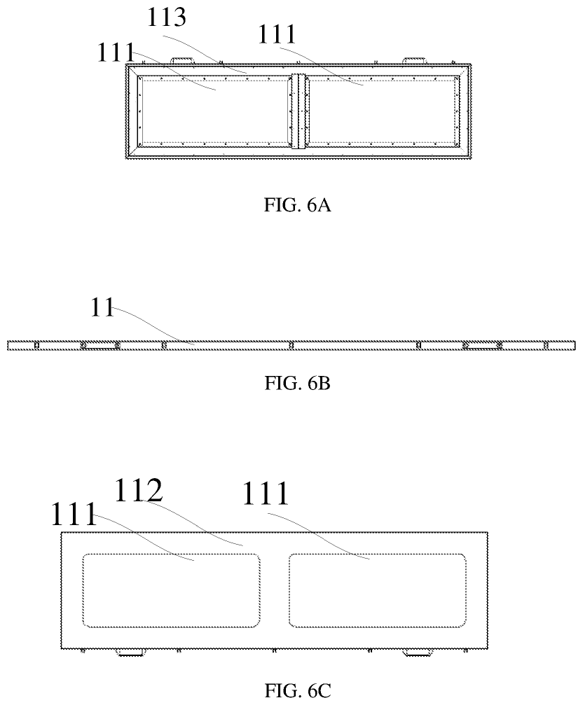

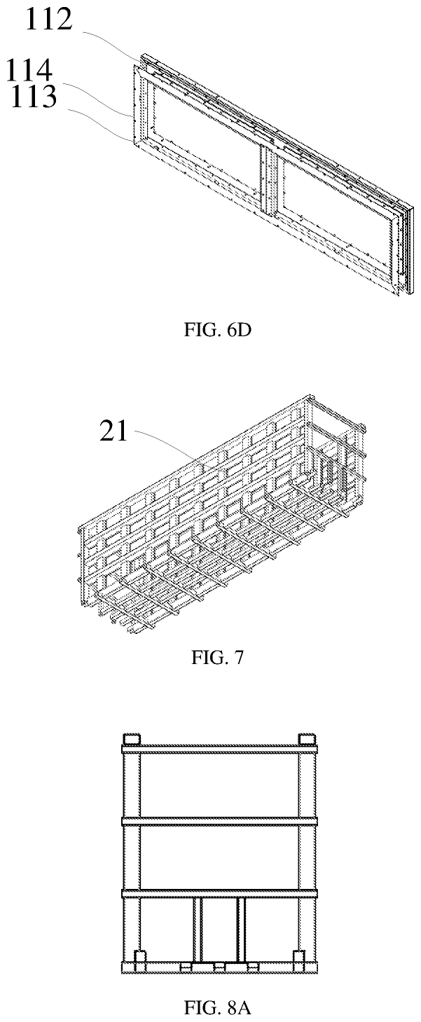

In the embodiments of the present disclosure, the liquid-cooled cabinet also includes a top cap 11 for covering the opening of the accommodation chamber 2. FIG. 5 is a schematic diagram of the top cap of the liquid-cooled cabinet according to an embodiment of the present disclosure. FIG. 6A is an upward view of FIG. 5, FIG. 6B is a top view of FIG. 5, FIG. 6C is a front view of FIG. 5, and FIG. 6D is a split view of FIG. 5. Referring to FIGS. 5 to 6D, the top cap 11 is provided with a visible window 111, which is made of a transparent material such as polycarbonate sheet. Operation and maintenance staff can observe internal situations of the liquid-cooled cabinet through the visible window 111.

The top cap 11 mainly includes a cap body 112 and a reinforcer 113, where the cap body 112 and the reinforcer 113 have the same size and shape, and are combined into a whole to form the top cap 11. The cap body 112 is generally exposed in air, and the reinforcer 113 is provided with a mounting hole 114, such as a nitrogen spring mounting hole, to mount a nitrogen spring. A tank of the inner liner 1 is provided with an air support bracket 12 for mounting the nitrogen spring. Opening of the top cap 11 is controlled by the nitrogen spring. In addition, installation of the mounting hole 114 for mounting the nitrogen spring at the reinforcer 113 can play a certain supporting role.

Alternatively, the inner liner 1 and the top cap 11 are sealed with a sealing material that does not react with the coolant in inner liner 1. After the top cap 11 is closed, a sealing strip is pressed down by means of a latch fastener to cause certain deformation of the sealing strip, thereby completing the sealing between the inner liner 1 and the top cap 11.

Alternatively, the liquid-cooled cabinet also includes a first protective element 21 formed by welding metal tubes and sleeved on an outer edge of the inner liner 1, where a metal tube comprised in a first sidewall of the first protective element forms a gap allowing the liquid inlet 6 and the liquid outlet 7 to stretch out, and a metal tube comprised in a second sidewall of the first protective element 21 forms a gap allowing the liquid inlet and the liquid outlet to stretch out.

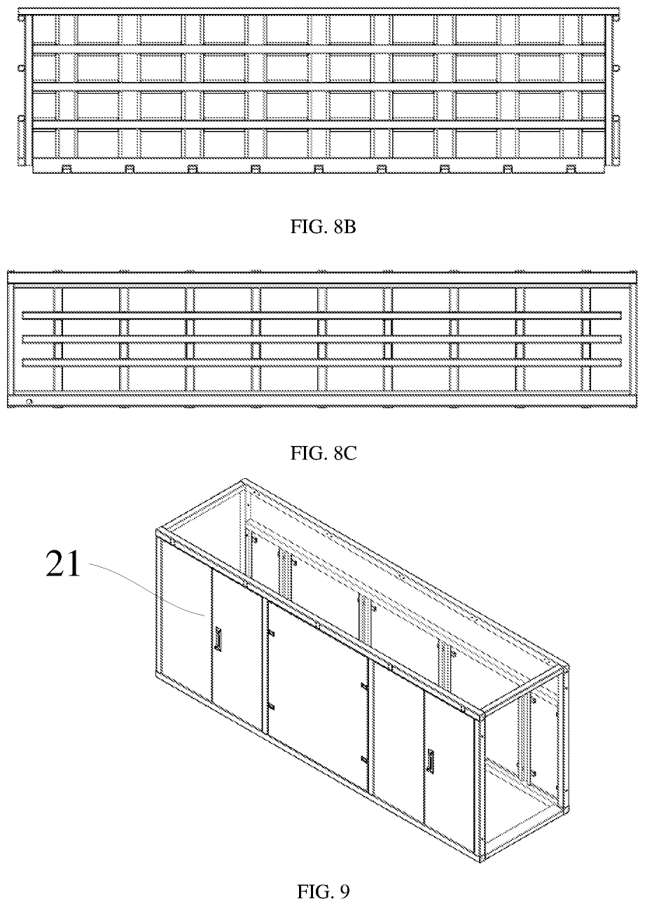

FIG. 7 is a schematic structural diagram of a first protective element of the liquid-cooled cabinet according to an embodiment of the present disclosure. FIG. 8A is a schematic diagram showing a left side surface of the first protective element shown in FIG. 7, FIG. 8B is a schematic diagram showing a front side surface of the first protective element shown in FIG. 7, and FIG. 8C is a schematic diagram showing a bottom surface of the first protective element shown in FIG. 7.

Referring to FIGS. 7 to 8C, the first protective element 21 is an integral structure formed by welding some 316 rectangular stainless steel tubes. Alternatively, five parts may be respectively welded to periphery of five side edges of the inner liner 1, thereby ultimately forming the complete first protective element 21.

In the embodiments of the present disclosure, the inner liner of the liquid-cooled cabinet is used to accommodate the coolant and the electronic device, where the coolant generally has a higher density. When the accommodation chamber 2 of the inner liner 1 is filled with the coolant, the high-density coolant is likely to deform the inner liner 1, and the deformation of the inner liner 1 may cause a problem such as failure of successful installation of the electronic device. Therefore, arrangement of the first protective element 21 can prevent the deformation of the inner liner 1.

Alternatively, the above-mentioned liquid-cooled cabinet also includes a second protective element 22 sleeved on an outer edge of the first protective element 21, a first sidewall and a second sidewall of the second protective element 22 are circular metal tubes, and a third sidewall and a fourth sidewall of the second protective element 22 are metal plates. The first sidewall is also referred to as a left sidewall, the second sidewall is also referred to as a right sidewall, the third sidewall is also referred to as a front sidewall, and the fourth sidewall is also referred to as a rear sidewall.

FIG. 9 is a schematic structural diagram of a second protective element of the liquid-cooled cabinet according to an embodiment of the present disclosure. Referring to FIG. 9, the second protective element 22 is formed by welding nondeformable metals of different specifications. For example, the first sidewall and the second sidewall are made of rectangular carbon steel tubes, while the third sidewall and the fourth sidewall are formed by welding five carbon steel plates, respectively. The carbon steel plates and the rectangular carbon steel tubes are welded together as a whole to form the second protective element 22. Welded to an outer side of the first protective element 21, the second protective element 22 can play a certain aesthetic effect and can further prevent the deformation of the inner liner 1.

Referring to FIG. 4D and FIG. 4F again, alternatively, in the above embodiment, the inner liner 1 is provided with a mounting bracket 23 for mounting a liquid level meter. In addition, the inner liner 1 is also provided with a temperature sensor mounting hole. For example, the first guide bar 15 or the second guide bar 16 is provided with a thermometer mounting hole for mounting a thermometer. The liquid level meter is used to detect liquid level changes of the coolant in the inner liner 1 at any time when the electronic device is running, to replenish the coolant at any time.

In addition, liquid level and temperature changes of the coolant inside the liquid-cooled cabinet may also be detected by means of a heat exchange system on two sides of the liquid-cooled cabinet, to give a series of low level alarms or high temperature alarms.

In the embodiments of the present disclosure, the liquid-cooled cabinet utilizes the liquid level meter to collect liquid level information, utilizes a temperature sensor to collect temperature information, and feeds back the liquid level information and the temperature information to the heat exchange system. The heat exchange system adjusts an inflow velocity of the coolant at the liquid inlet and an outflow velocity of the heat flow at the liquid outlet based on the temperature information and the liquid level information, such that the temperature of the accommodation chamber 2 is kept within a reasonable range. After the heat flow is discharged from the liquid outlet, it may be cooled down by means of natural cooling, which can greatly reduce energy consumption.

Referring to FIG. 4G again, alternatively, in the above embodiment, the electronic device is powered by dual PDUs. A bidirectional mounting hole 24 is arranged on the third sidewall of the accommodation chamber 2. By supplying power with dual PDUs, when one PDU27 goes wrong, the other PDU27 can still continue supplying power to the electronic device, such that the electronic device can operate normally. After the PDU27 is built in, a sealing strip in a preset shape is additionally arranged between the PDU27 and a third side stainless steel plate to meet the sealing between the PDU27 and the outside, thereby ensuring airtightness of the accommodation chamber 2 of the inner liner 1. After the PDU27 is built in, number of cables of the electronic device passing through the inner liner 1 is reduced, thereby avoiding the problem of vaporization and leakage of the coolant.

Referring to FIG. 4G and FIG. 4H, a cable binding bracket 25 and a cable slot mounting bracket 26 are arranged in the inner liner 1. Cables of the electronic device are fixed through the cable binding bracket 25 and the cable slot mounting bracket to avoid disorderly and tanglesome arrangement of the cables of the electronic device, such that the operation and maintenance staff can quickly find the cables, thereby achieving the objective of improving the operating efficiency.

Other embodiments of the present disclosure will be apparent to those skilled in the art from consideration of the specification and practice of the invention disclosed here. The present disclosure is intended to cover any variations, uses, or adaptations of the present disclosure following the general principles thereof and including such departures from the present disclosure as come within known or customary practice in the art. It is intended that the specification and embodiments be considered as exemplary only, with a true scope and spirit of the present disclosure being indicated by the following claims.

It will be appreciated that the present disclosure is not limited to the exact construction that has been described above and illustrated in the accompanying drawings, and that various modifications and changes can be made without departing from the scope thereof. It is intended that the scope of the present disclosure only be limited by the appended claims.

What is claimed is:

1. A liquid-cooled cabinet comprising:
an inner liner having an open accommodation chamber internally provided with a flow equalizing plate, wherein a coolant cavity for coolant injection is formed between the flow equalizing plate and a bottom surface of the accommodation chamber, the flow equalizing plate is provided with multiple rows of first through-holes for a coolant to pass through, space above each row of the first through-holes is configured for deploying an electronic device, and a main body of the electronic device is provided with a second through-hole, such that the coolant enters the main body of the electronic device through the second through-hole;
at least one liquid inlet arranged on a first sidewall and a second sidewall of the inner liner, wherein a drainage portion is arranged on a bottom of the first sidewall and a bottom of the second sidewall, a splitter cavity is arranged below the drainage portion, a top surface of the splitter cavity is flush with the flow equalizing plate, the liquid inlet leads to the drainage portion, and the first sidewall and the second sidewall are two opposite sidewalls of the accommodation chamber;
at least one liquid outlet arranged on the first sidewall and the second sidewall, wherein a position of the liquid outlet is higher than a position of the liquid inlet;
a backwater cavity arranged on the first sidewall and the second sidewall and keeping away from the drainage portion, wherein an inlet of the backwater cavity is positioned in upper space of the accommodation chamber, an outlet of the backwater cavity is connected to the liquid outlet, and the upper space is space above the electronic device; and
a top cap covering an opening of the accommodation chamber.

2. The liquid-cooled cabinet according to claim 1, wherein
a first guide bar is arranged on a third sidewall of the accommodation chamber, and a second guide bar is arranged on a fourth sidewall of the accommodation chamber, the first guide bar and the second guide bar being configured to guide the electronic device to enter the accommodation chamber, the third sidewall and the fourth sidewall being two opposite sidewalls of the accommodation chamber.

3. The liquid-cooled cabinet according to claim 2, wherein
a first mounting plate is arranged on the third sidewall of the accommodation chamber, a second mounting plate is arranged on the fourth sidewall of the accommodation chamber, the first mounting plate and the second mounting plate are respectively provided with a mounting hole; when the electronic device is inserted in place under a guidance of the first guide bar and the second guide bar, a nut on the electronic device is locked with the mounting hole.

4. The liquid-cooled cabinet according to claim 3, wherein
a flow baffle is arranged on the third sidewall of the accommodation chamber, the flow baffle being arranged behind the first mounting plate to prevent the coolant from entering a power supply unit of the electronic device.

5. The liquid-cooled cabinet according to claim 4 further comprising:
a filling block arranged between the drainage portion and the backwater cavity.

6. The liquid-cooled cabinet according to claim 4 further comprising:
a first protective element formed by welding metal tubes and sleeved on an outer edge of the inner liner, wherein a metal tube comprised in a first sidewall of the first protective element forms a gap allowing the liquid inlet and the liquid outlet to stretch out, and a metal tube comprised in a second sidewall of the first protective element forms a gap allowing the liquid inlet and the liquid outlet to stretch out.

7. The liquid-cooled cabinet according to claim 6 further comprising:
a second protective element sleeved on an outer edge of the first protective element, a first sidewall and a second sidewall of the second protective element being circular metal tubes, a third sidewall and a fourth sidewall of the second protective element being metal plates.

8. The liquid-cooled cabinet according to claim 4, wherein
the top cap comprises a cap body and a reinforcer fitting with each other, the cap body is exposed to air, the reinforcer faces towards the coolant in the accommodation chamber, and a visible window is arranged on the top cap.

9. The liquid-cooled cabinet according to claim 4, wherein
the inlet of the backwater cavity is provided with a mounting bracket configured for mounting a liquid level meter.

10. A data center computer room comprising a computer room and a liquid-cooled cabinet, wherein the liquid-cooled cabinet comprises:
an inner liner having an open accommodation chamber internally provided with a flow equalizing plate, wherein a coolant cavity for coolant injection is formed between the flow equalizing plate and a bottom surface of the accommodation chamber, the flow equalizing plate is provided with multiple rows of first through-holes for a coolant to pass through, space above each row of the first through-holes is configured for deploying an electronic device, and a main body of the electronic device is provided with a second through-hole, such that the coolant enters the main body of the electronic device through the second through-hole;
at least one liquid inlet arranged on a first sidewall and a second sidewall of the inner liner, wherein a drainage portion is arranged on a bottom of the first sidewall and a bottom of the second sidewall, a splitter cavity is arranged below the drainage portion, a top surface of the splitter cavity is flush with the flow equalizing plate, the liquid inlet leads to the drainage portion, and the first sidewall and the second sidewall are two opposite sidewalls of the accommodation chamber;
at least one liquid outlet arranged on the first sidewall and the second sidewall, wherein a position of the liquid outlet is higher than a position of the liquid inlet;
a backwater cavity arranged on the first sidewall and the second sidewall and keeping away from the drainage portion, wherein an inlet of the backwater cavity is positioned in upper space of the accommodation chamber, an outlet of the backwater cavity is connected to the liquid outlet, and the upper space is space above the electronic device; and
a top cap covering an opening of the accommodation chamber.

11. The data center computer room according to claim 10, wherein
a first guide bar is arranged on a third sidewall of the accommodation chamber, and a second guide bar is arranged on a fourth sidewall of the accommodation chamber, the first guide bar and the second guide bar being configured to guide the electronic device to enter the accommodation chamber, the third sidewall and the fourth sidewall being two opposite sidewalls of the accommodation chamber.

12. The data center computer room according to claim 11, wherein
a first mounting plate is arranged on the third sidewall of the accommodation chamber, a second mounting plate is arranged on the fourth sidewall of the accommodation chamber, the first mounting plate and the second mounting plate are respectively provided with a mounting hole; when the electronic device is inserted in place under a guidance of the first guide bar and the second guide bar, a nut on the electronic device is locked with the mounting hole.

13. The data center computer room according to claim 12, wherein
a flow baffle is arranged on the third sidewall of the accommodation chamber, the flow baffle being arranged behind the first mounting plate to prevent the coolant from entering a power supply unit of the electronic device.

14. The data center computer room according to claim 13 further comprising:
a filling block arranged between the drainage portion and the backwater cavity.

15. The data center computer room according to claim 13 further comprising:
a first protective element formed by welding metal tubes and sleeved on an outer edge of the inner liner, wherein a metal tube comprised in a first sidewall of the first protective element forms a gap allowing the liquid inlet and the liquid outlet to stretch out, and a metal tube comprised in a second sidewall of the first protective element forms a gap allowing the liquid inlet and the liquid outlet to stretch out.

16. The data center computer room according to claim 15 further comprising:
a second protective element sleeved on an outer edge of the first protective element, a first sidewall and a second sidewall of the second protective element being circular metal tubes, a third sidewall and a fourth sidewall of the second protective element being metal plates.

17. The data center computer room according to claim 13, wherein
the top cap comprises a cap body and a reinforcer fitting with each other, the cap body is exposed to air, the reinforcer faces towards the coolant in the accommodation chamber, and a visible window is arranged on the top cap.

18. The data center computer room according to claim 15, wherein
the inlet of the backwater cavity is provided with a mounting bracket configured for mounting a liquid level meter.
